(19) United States
(12) Patent Application Publication
(10) Pub. No.: US 2005/0024841 A1
(43) Pub. Date: Feb. 3, 2005

(54) Circuit board that comprises one or more mounting pins

(76) Inventors: Robert William Dobbs, Granite Bay, CA (US); Stephan Karl Barsun, Davis, CA (US); Andrew Harvey Barr, Roseville, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/631,080

(22) Filed: Jul. 31, 2003

(51) Int. Cl. H05K 7/02; H05K 7/04

(52) U.S. Cl. 361/810

(57) ABSTRACT

A circuit board of an apparatus in one example comprises one or more mounting pins that connect the circuit board with a chassis.

### BACKGROUND

In one example, a card guide connects the circuit board with the chassis. The chassis in one example comprises a computer case and/or card cage. During installation of the circuit board into the chassis, the circuit board slides along an installation path in the card guide. The chassis in one example comprises a backplane at the end of the installation path to receive the circuit board. For example, the backplane comprises one or more sockets to electrically and mechanically couple with the circuit board. During installation, the circuit board slides along the installation path in the card guide to an engagement with the backplane.

The backplane in one example fills a depth in the chassis of around two to six centimeters (around one to two inches). The card guide may provide a plurality of installation paths for a plurality of circuit boards. The plurality of installation paths lead the plurality of circuit boards to a plurality of the sockets on the backplane. The distance of separation of the plurality of circuit boards is determined based on a distance of separation between the sockets of the backplane.

In another example, one or more standoff components connect a circuit board with a chassis. One standoff component in one example attaches to each corner of the circuit board and the chassis to couple the circuit board with the chassis.

### SUMMARY

The invention in one embodiment encompasses an apparatus. The apparatus comprises a circuit board that comprises one or more mounting pins that connect the circuit board with a chassis.

Another embodiment of the invention encompasses an apparatus. The apparatus comprises a chassis that comprises one or more holes to receive one or more mounting pins of a circuit board. The one or more holes of the chassis allow the chassis to support the one or more mounting pins to connect the circuit board with the chassis.

Yet another embodiment of the invention encompasses an apparatus. The apparatus comprises means for attaching one or more mounting pins to a circuit board. The apparatus comprises means for receiving the one or more mounting pins of the circuit board in a chassis. The means for receiving the one or more mounting pins support the one or more mounting pins to connect the circuit board with the chassis.

A further embodiment of the invention encompasses a method. One or more mounting pins of a circuit board are inserted into one or more holes in a chassis to connect the circuit board with the chassis.

### DESCRIPTION OF THE DRAWINGS

Features of exemplary implementations of the invention will become apparent from the description, the claims, and the accompanying drawings in which:

FIG. 1 is a representation of a front view of an exemplary implementation of an apparatus that comprises one or more circuit boards and a chassis.

FIG. 2 is a representation of a back view of the one or more circuit boards and the chassis of the apparatus of FIG. 1.

FIG. 3 is a representation of a side view of the one or more circuit boards and the chassis of the apparatus of FIG. 1.

FIG. 4 is a representation of a front view of another exemplary implementation of the one or more circuit boards and the chassis of the apparatus of FIG. 1.

FIG. 5 is a representation of a back view of the one or more circuit boards and the chassis of the apparatus of FIG. 4.

FIG. 6 is a representation of an initiation of an installation of one of the one or more circuit boards into the chassis of the apparatus of FIG. 1.

FIG. 7 is a representation of a completion of an installation of one of the one or more circuit boards into the chassis of the apparatus of FIG. 1.

FIG. 8 is a representation of an initiation of an installation of a first circuit board and a second circuit board of the one or more circuit boards into the chassis of the apparatus of FIG. 1.

FIG. 9 is a representation of a completion of an installation of a first circuit board and a second circuit board of the one or more circuit boards into the chassis of the apparatus of FIG. 1.

### DETAILED DESCRIPTION

As described above, the backplane in one example fills a depth in the chassis of around two to six centimeters. As one shortcoming, the backplane takes up space within the chassis that could otherwise be used for additional circuit boards or other computer components. The distance of separation of the plurality of circuit boards is determined based on a distance of separation between the sockets of the backplane. As another shortcoming, the distance of separation between the plurality of circuit boards limits a number of circuit boards able to fit within the chassis. One standoff component in one example attaches to each corner of the circuit board and the chassis to couple the circuit board with the chassis. As one shortcoming of the standoff components, the chassis requires a flat planar surface to mount the standoff components. As another shortcoming of the standoff components, tools are required to install the standoff components to the circuit board and the chassis.

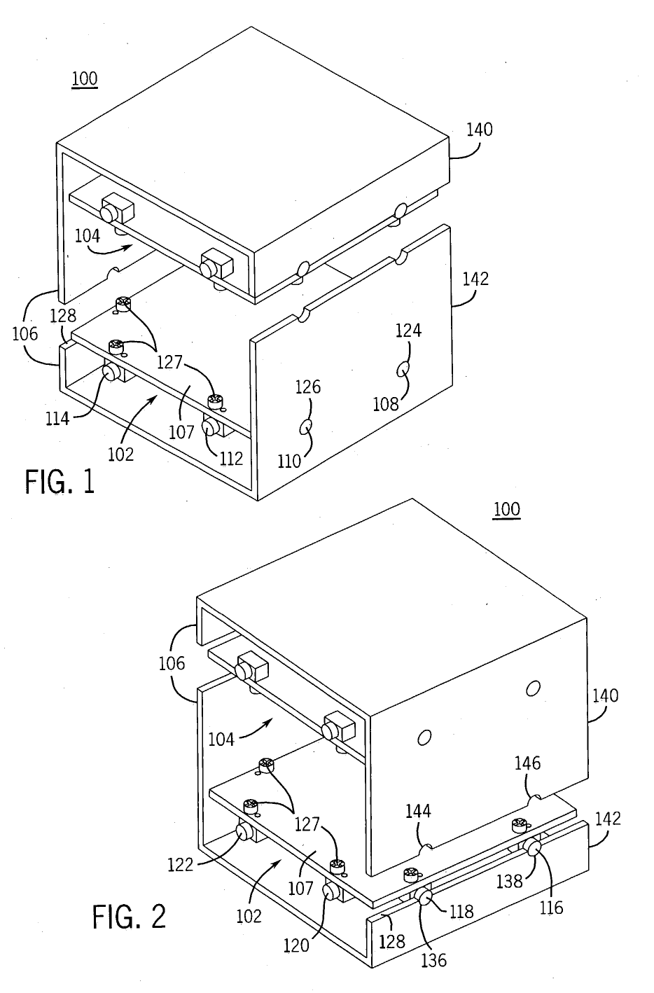

Turning to FIG. 1, an apparatus 100 in one example comprises a plurality of components such as hardware components. A number of such components can be combined or divided in one example of the apparatus 100. The apparatus 100 in one example comprises any (e.g., horizontal, oblique, or vertical) orientation, with the description and figures herein illustrating one exemplary orientation of the apparatus 100, for explanatory purposes.

Referring to FIGS. 1 and 2, the apparatus 100 in one example comprises one or more circuit boards 102 and 104 and a chassis 106. The circuit board 102 in one example comprises a printed circuit board (“PCB”) portion 107 and one or more mounting pins, for example, one or more of mounting pins 108, 110, 112, 114, 116, 118, 120, and 122. The chassis 106 in one example comprises one or more holes, for example, one or more of holes 124 and 126.

The printed circuit board portion 107 of the circuit board 102 in one example comprise two faces and four edges. The mounting pins 108, 110, 112, 114, 116, 118, 120, and 122 are connected with the printed circuit board portion 107 on one or more of the faces of the printed circuit board portion 107. The mounting pins 108, 110, 112, 114, 116, 118, 120, and 122 may protrude from one, two, three, or all four edges of the printed circuit board portion 107. The mounting pins 108, 110, 112, 114, 116, 118, 120, and 122 are located on one or more peripheral portions of the circuit board 102. For example, the mounting pins 108 and 110 are connected to the printed circuit board portion 107 substantially near a first edge on a first peripheral portion of the printed circuit board portion 107. The mounting pins 116 and 118 are connected to the printed circuit board portion 107 substantially near a second edge on a second peripheral portion of the printed circuit board portion 107. The mounting pins 108, 110, 116, and 118 in one example protrude outside of a perimeter of the printed circuit board portion 107.

In one example, one or more connection components 127 attach the mounting pins 108, 110, 112, 114, 116, 118, 120, and 122 with the printed circuit board portion 107. The connection components 127 in one example comprise one or more of screws, connection pins, clips, rivets, press-fittings, press pins, through hole soldering, solder with mechanical connection, quarter-turn fasteners, swages, and snap-ins. Where the connection components 127 comprises screws, the screws couple the mounting pins 108, 110, 112, 114, 116, 118, 120, and 122 with circuit board 102. For example, the screws pass through holes in the circuit board 102 and into the mounting pins 108, 110, 112, 114, 116, 118, 120, and 122.

In another example, the mounting pins 108, 110, 112, 114, 116, 118, 120, and 122 are a part of the printed circuit board portion 107. For example, the mounting pins 108, 110, 112, 114, 116, 118, 120, and 122 and the printed circuit board portion 107 comprise a unitary construction and/or integral formation. A peripheral portion of the printed circuit board portion 107 in one example is formed into a mounting structure, for example, one or more of the mounting pins 108, 110, 112, 114, 116, 118, 120, and 122. The peripheral portion of the printed circuit board portion 107 attaches with a support structure of the chassis 106. For example, the mounting structure comprises one or more protrusions and the chassis 106 comprises one or more recesses to receive the one or more protrusions.

The connection components 127 comprise one or more alignment components. The alignment components in one example comprise alignment pins that mate with alignment holes in the printed circuit board portion 107. The alignment pins and alignment holes prevent rotation of the mounting pins 108, 110, 112, 114, 116, 118, 120, and 122 relative to the printed circuit board portion 107. For example, one of the alignment pins prevents a misalignment between the mounting pin 110 and the hole 126. The alignment component in one example abuts an edge of the printed circuit board portion 107 to prevent rotation of the mounting pins 108, 110, 112, 114, 116, 118, 120, and 122.

The mounting pins 108, 110, 112, 114, 116, 118, 120, and 122 in one example comprise retractable mounting pins. The mounting pins 108 and 110 may retract upon contact with the chassis 106. For example, a protrusion of the mounting pins 108 and 110 may retract into a pin chamber of the mounting pins 108 and 110 upon contact with the chassis 106. Once the protrusion of the mounting pins 108 and 110 enters the pin chamber of the mounting pins 108 and 110 the mounting pins 108 and 110 are in a retracted position. The mounting pins 108 and 110 may then extend from the retracted position upon alignment with the holes 124 and 126 of the chassis 106 to engage with the holes 124 and 126 of the chassis 106.

In one example, the mounting pins 108 and 110 comprise one or more spring loaded extension components. In another example, one or more hand screws extend the mounting pins 108 and 110 to engage with the holes 124 and 126. For example, upon alignment of the mounting pins 108 and 110 with the holes 124 and 126, an operator twists the hand screws to extend the mounting pins 108 and 110 into the holes 124 and 126. In yet another example, the mounting pins 108 and 110 comprise compliant members. The compliant members deform upon contact with the chassis 106 and then extend into the holes 124 and 126 upon alignment with the holes 124 and 126. For example, the mounting pins 108 and 110 comprise compliant plastic or metal beams.

The mounting pins 108 and 110 and the holes 124 and 126 in one example comprise a keying system. For example, the holes 124 and 126 are designed to limit acceptance to mounting pins that match a position of the holes 124 and 126. The mounting pins 108 and 110 and the holes 124 and 126 comprise a unique alignment to allow insertion of the mounting pins 108 and 110 into the holes 124 and 126. Different sides of the circuit board 102 could have different pin alignments to prevent an improper connection between the circuit board 102 and the chassis 106. The circuit board 102 could have a different pin alignment than the circuit board 104 to prevent an engagement between the circuit board 104 and a position on the chassis 106 intended for the circuit board 102.

In one example, the holes 124 and 126 are spaced at a certain distance to only accept mounting pins separated at the same distance as the holes 124 and 126. In another example, the holes 124 and 126 are a certain size to only accept mounting pins of the same size as the holes 124 and 126. In yet another example, the holes 124 and 126 are a certain shape to only accept mounting pins of the same shape as the holes 124 and 126.

The chassis 106 comprises a frame to house the circuit boards 102 and 104. The chassis 106 in one example comprises a computer case. The chassis 106 comprises one or more support components to connect the circuit boards 102 and 104 with the chassis 106. For example, the chassis 106 comprises one or more of the holes 124 and 126 and a ledge 128 able to receive and support one or more of the mounting pins 108, 110, 112, 114, 116, 118, 120, and 122 of the circuit board 102.

The holes 124 and 126 allow the chassis 106 to support the mounting pins 108 and 110. For example, the holes 124 and 126 receive the pins 108 and 110 to connect the circuit board 102 with the chassis 106. The holes 124 and 126 comprise a diameter that is large enough to receive the mounting pins 108 and 110. The diameter in one example is also large enough to allow an angled insertion of the mounting pins 108 and 110 into the holes 124 and 126 of the chassis 106. For example, the first peripheral portion of the printed circuit board portion 107 that comprises the mounting pins 108 and 110 is lowered into the chassis 106 at an angle to engage the mounting pins 108 and 110 with the holes 124 and 126 before attaching the second peripheral portion of the printed circuit board portion 107 that comprises the mounting pins 108 and 110 with the ledge 128.

A retainer component in one example serves to hold the mounting pins 108 and 110 in the holes 124 and 126 of the chassis 106 after insertion of the mounting pins 108 and 110 into the holes 124 and 126. For example, the retainer component prevents a movement of the mounting pins 108 and 110 in the holes 124 and 126. In one example, the mounting pins 108 and 110 comprise cylindrical members, therefore the holes 124 and 126 comprise circular holes sized to receive the cylindrical members. In another example, the mounting pins 108 and 110 comprise tabs, therefore the holes 124 and 126 comprise slots sized to receive the tabs.

The ledge 128 supports a portion of the circuit board 102. For example, upon an abutment of the circuit board 102 with the ledge 128, the ledge 128 supports the circuit board 102. The ledge 128 in one example comprise one or more recesses 136 and 138 to support one or more of the mounting pins 108, 110, 112, 114, 116, 118, 120, and 122 of the circuit board 102. The recesses 136 and 138 in one example comprise one or more of grooves, supports, guides, and indentations in the ledge 128. The mounting pins 116 and 118 in one example rest in the recesses 136 and 138 on the ledge 128. The recesses 136 and 138 limit a movement of the mounting pins 116 and 118 on the ledge 128.

In one example, the chassis 106 comprises a single integral chassis component. In another example, the chassis 106 comprises a chassis cover component 140 and a chassis base component 142. The chassis cover component 140 meets with the chassis base component 142 to enclose or partially enclose the circuit boards 102 and 104 within the chassis 106. The chassis cover component 140 in one example comprises one or more recesses 140 and 142. The recesses 136 and 138 on the ledge 128 support the mounting pins 116 and 118. For example, a bottom portion of the mounting pins 116 and 118 abuts the ledge 128 in the recesses 136 and 138. In one example, upon closure of the chassis cover component 140 with the chassis base component 142, the recesses 140 and 142 of the chassis cover component 140 abut a top portion of the mounting pins 116 and 118 to hold the mounting pins 116 and 118 against the ledge 128 in the recesses 136 and 138. In another example, a retainer component (e.g., analogous to the retainer component 702 (FIG. 7)) within the chassis 106 abuts the mounting pins 116 and 118 to hold the mounting pins 116 and 118 against the ledge 128.

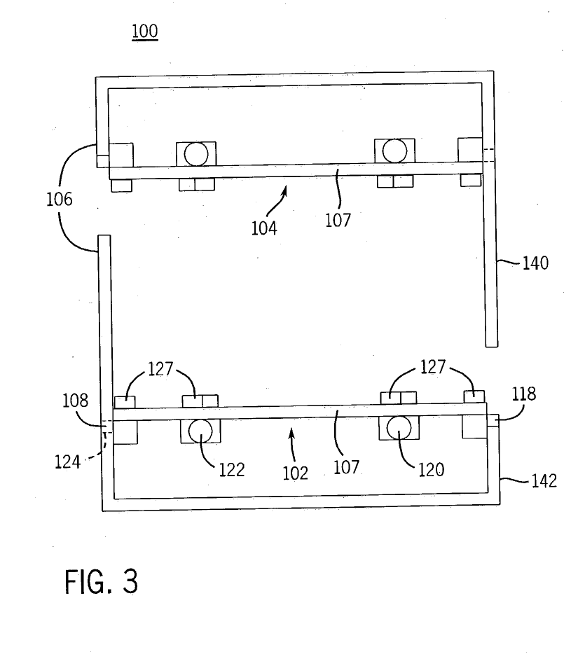

Turning to FIG. 3, the printed circuit board portions 107 of the circuit boards 102 and 104 in one example fit within the chassis 106. For example, the chassis cover component 140 may abut with the chassis base component 142 without interference from the printed circuit board portions 107.

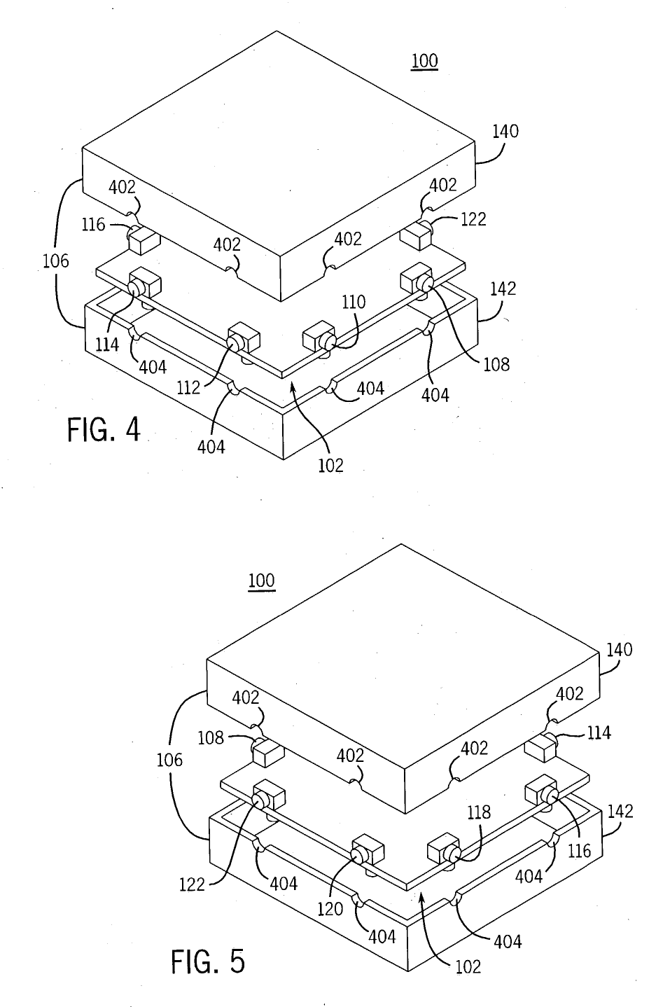

Turning to FIGS. 4 and 5, the chassis 106 in one example comprises the chassis cover component 140 and the chassis base component 142. The chassis cover component 140 and the chassis base component 142 comprise recesses to mount the circuit board with the chassis 106. For example, the chassis cover component 140 comprises one or more recesses 402 and the chassis base component 142 comprises one or more recesses 404. The recesses 402 are substantially similar to the recesses 144 and 146 and the recesses 404 are substantially similar to the recesses 136 and 138, as described herein. The recesses 404 support the bottom portion of the mounting pins 108, 110, 112, 114, 116, 118, 120, and 122 of the circuit board 102 to connect the circuit board 102 with the chassis 106. The recesses 404 of the chassis cover component 140 abut the top portion of the mounting pins 108, 110, 112, 114, 116, 118, 120, and 122 of the circuit board 102 to complete a connection between the circuit board 102 and the chassis 106. For example, upon closure of the chassis cover component 140 and the chassis base component 142, the recesses 402 and 404 limit a movement of the circuit board 102 within the chassis 106.

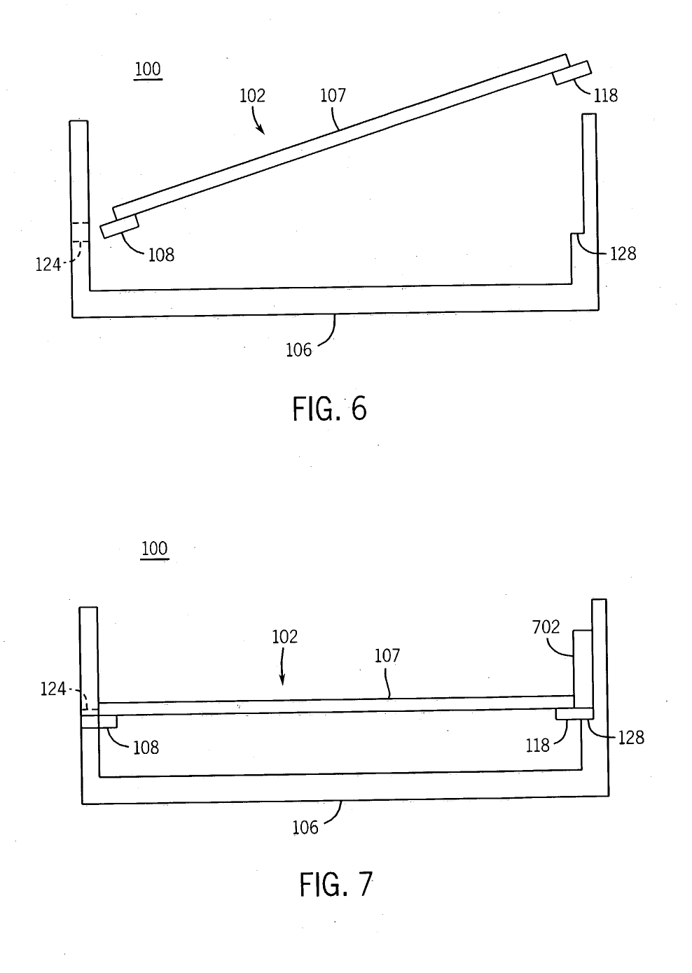

Referring to FIGS. 1 and 6, an illustrative description of one exemplary operation of the apparatus 100 is now presented, for explanatory purposes. Installation of the apparatus 100 in one example comprises a connection of the circuit board 102 with the chassis 106. The mounting pins 108, 110, 112, 114, 116, 118, 120, and 122 promote a tool-less installation and servicing of the circuit board 102. The mounting pins 108 and 110 in one example are located on a first peripheral portion of the circuit board 102. The mounting pins 116 and 118 in one example are located on a second peripheral portion of the circuit board 102. To connect the first peripheral portion of the circuit board 102 with the chassis 106, the mounting pins 108 and 110 are inserted into the holes 124 and 126 of the chassis 106, respectively. The chassis 106 supports the first peripheral portion of the circuit board 102 by holding the mounting pins 108 and 110 in the holes 124 and 126.

Referring to FIGS. 1 and 7, upon engagement of the mounting pins 108 and 110 with the holes 124 and 126 of the chassis 106, the second peripheral portion of the circuit board 102 is pivotably lowered about the engagement into the chassis 106. The second peripheral portion of the circuit board 102 is lowered until abutment of the mounting pins 116 and 118 with the ledge 128. The ledge 128 supports the second peripheral portion of the circuit board 102.

One or more retainer components 702 in one example serve to hold the second peripheral portion of the circuit board 102 against the ledge 128. The retainer component 702 prevents a movement of the circuit board 102. For example, the retainer component 702 holds the second peripheral portion of the circuit board 102 against the ledge 128 to prevent a disengagement of the mounting pins 116 and 118 from the ledge 128. In one example, the retainer component 702 comprises a block or sheet metal plate fastened or pivotably mounted to the chassis 106, one or more springs, clips, push pins, shuttles, or slide retainers. In another example, the retainer component 702 comprises a portion of the chassis 106. For example, the chassis cover component 140 may hold the mounting pins 116 and 118 against the ledge 128. The recesses 136 and 138 of the chassis base component 142 align with the recesses 144 and 146 of the chassis cover component 140 to hold the mounting pins 116 and 118.

To remove the circuit board 102 from the chassis 106, the retainer component 702 is released from the second peripheral portion of the circuit board 102. The second peripheral portion of the circuit board 102 is raised off of the ledge 128. Then, the mounting pins 108 and 110 are backed out of the holes 124 and 126 to release the circuit board 102 from the chassis 106.

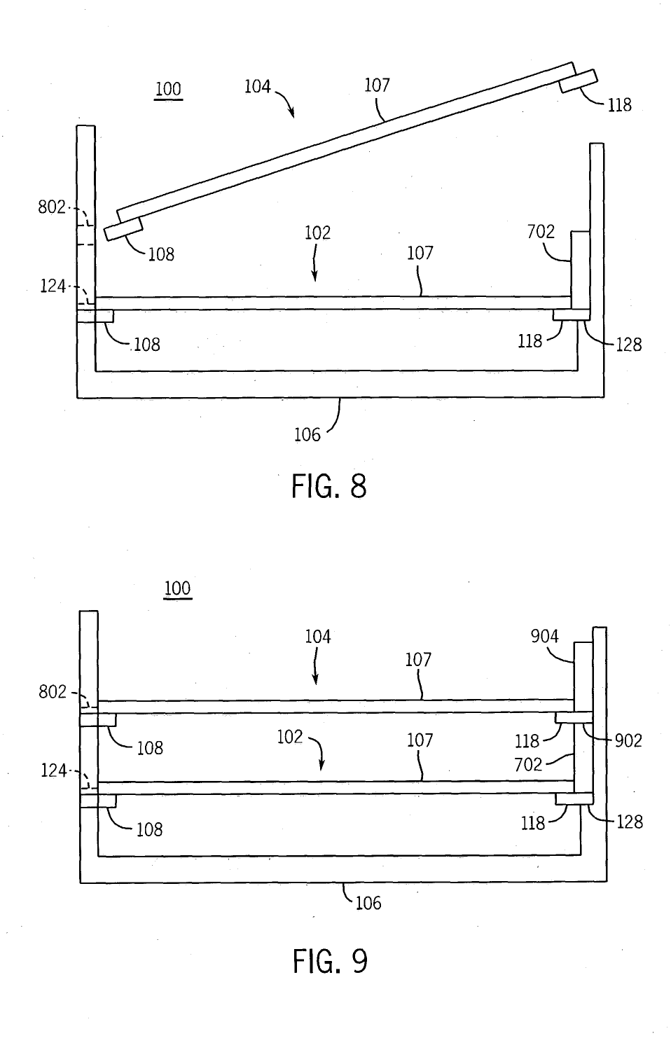

Referring to FIGS. 1 and 8, the installation of the apparatus 100 in one example comprises a connection of the circuit board 102 and the circuit board 104 with the chassis 106. One or more additional circuit boards (e.g., analogous to one or more of the circuit boards 102 and 104) may be connected with the chassis 106 along with the circuit boards 102 and 104, as will be appreciated by those skilled in the art. Employing one or more of the mounting pins 108, 110, 112, 114, 116, 118, 120, and 122 to connect the circuit boards 102 and 104 with the chassis 106 allows for a short distance of separation between the circuit board 102 and the circuit board 104. Thus, the use of the mounting pins 108, 110, 112, 114, 116, 118, 120, and 122 to connect the circuit boards 102 and 104 with the chassis 106 promotes denser packaging within the chassis 106.

The connection of the circuit board 104 with the chassis 106 is substantially similar to the connection of the circuit board 102 with the chassis 106, as described herein. For example, the mounting pins 108 and 110 of the circuit board 104 are inserted into holes 802 in the chassis 106. The chassis 106 supports a first peripheral portion of the circuit board 104 by holding the mounting pins 108 and 110 of the circuit board 104 in the holes 124 and 126.

Referring to FIGS. 1 and 9, upon engagement of the mounting pins 108 and 110 of the circuit board 104 with the holes 802 of the chassis 106, a second peripheral portion of the circuit board 104 is pivotably lowered about the engagement into the chassis 106. The second peripheral portion of the circuit board 104 is lowered until abutment of the mounting pins 116 and 118 of the circuit board 104 with a ledge 902 of the retainer component 702. The ledge 902 supports the second peripheral portion of the circuit board 104. The circuit boards 102 and 104 in one example are electrically connected through ribbon cables or electrical pin and socket connectors. A retainer component 904 in one example serves to hold the second peripheral portion of the circuit board 104 against the ledge 902. The retainer component 904 is substantially similar to the retainer component 702 and the circuit board 104 is removed from the chassis 106 analogously to the circuit board 102, as described herein.

The steps or operations described herein are just exemplary. There may be many variations to these steps or operations without departing from the spirit of the invention. For instance, the steps may be performed in a differing order, or steps may be added, deleted, or modified.

Although exemplary implementations of the invention have been depicted and described in detail herein, it will be apparent to those skilled in the relevant art that various modifications, additions, substitutions, and the like can be made without departing from the spirit of the invention and these are therefore considered to be within the scope of the invention as defined in the following claims.

1. An apparatus, comprising:
a circuit board that comprises one or more mounting pins that connect the circuit board with a chassis.

2. The apparatus of claim 1, wherein the chassis comprises one or more holes, wherein one or more of the one or more mounting pins are inserted into the one or more holes of the chassis to mount the circuit board into the chassis.

3. The apparatus of claim 2, wherein the circuit board comprises a first peripheral portion and a second peripheral portion;
wherein the first peripheral portion comprises the one or more of the one or more mounting pins that are inserted into the one or more holes of the chassis, wherein the chassis with the one or more holes supports the first peripheral portion of the circuit board;
wherein the chassis comprises a ledge, wherein upon an abutment of the second peripheral portion with the ledge, the ledge supports the second peripheral portion of the circuit board.

4. The apparatus of claim 3, further comprising a retainer component, wherein the retainer component serves to hold the second peripheral portion against the ledge.

5. The apparatus of claim 3, further comprising a retainer component, wherein the retainer component serves to hold the one or more of the one or more mounting pins in the one or more holes of the chassis.

6. The apparatus of claim 2, wherein the one or more mounting pins comprise one or more tabs, wherein the one or more holes of the chassis comprise one or more slots to receive the one or more tabs.

7. The apparatus of claim 1, wherein the circuit board comprises a printed circuit board and the one or more mounting pins, wherein the printed circuit board comprises a first peripheral portion and a second peripheral portion;
wherein a first mounting pin of the one or more mounting pins is attached to the first peripheral portion, wherein a second mounting pin of the one or more mounting pins is attached to the second peripheral portion.

8. The apparatus of claim 7, wherein the chassis comprises one or more ledges, wherein the one or more ledges comprise one or more recesses;
wherein the first mounting pin on the first peripheral portion of the printed circuit board rests on a first recess of the one or more recesses on one of the one or more ledges, wherein the second mounting pin on the second peripheral portion of the printed circuit board rests on a second recess of the one or more recesses on one of the one or more ledges.

9. The apparatus of claim 8, further comprising one or more retainer components, wherein the one or more retainer components hold the first and second mounting pins against the chassis in the first and second recesses to connect the circuit board with the chassis.

10. The apparatus of claim 9, wherein the chassis comprises a chassis base component, wherein the retainer component comprises a chassis cover component;
wherein chassis cover component comprises one or more recesses, wherein upon connection of the chassis base component and the chassis cover component, one or more of the one or more recesses of the chassis base component align with one or more of the one or more recesses of the chassis cover component to hold the first and second mounting pins.

11. The apparatus of claim 7, wherein the first and second mounting pins protrude outside of a perimeter of the printed circuit board.

12. The apparatus of claim 11, wherein the chassis comprises a hole and a ledge, wherein the first mounting pin on the first peripheral portion of the printed circuit board is inserted into the hole in the chassis, wherein the second mounting pin on the second peripheral portion of the printed circuit board rests on the ledge.

13. The apparatus of claim 12, wherein the ledge comprises one or more recesses to receive the second mounting pin on the second peripheral portion of the printed circuit board.

14. The apparatus of claim 12, wherein support of the first and second mounting pins by the hole and the ledge completes a mount of the printed circuit board in the chassis.

15. The apparatus of claim 1, wherein one or more of the one or more mounting pins retract upon contact with the chassis, wherein the one or more of the one or more mounting pins extend upon alignment with one or more holes of the chassis to engage with the one or more holes of the chassis.

16. The apparatus of claim 15, wherein the one or more mounting pins comprise one or more spring loaded extension components.

17. The apparatus of claim 1, wherein the one or more mounting pins comprise one or more integral formations of a peripheral portion of the circuit board.

18. The apparatus of claim 1, wherein the chassis comprises one or more holes, wherein the one or more mounting pins and the one or more holes comprise a keying system.

19. The apparatus of claim 18, wherein the one or more mounting pins are designed to only fit within the one or more holes if the one or more holes comprise a position, size, and shape that match a position, size, and shape of the one or more mounting pins.

20. An apparatus, comprising:
a chassis that comprises one or more holes to receive one or more mounting pins of a circuit board, wherein the one or more holes of the chassis allow the chassis to support the one or more mounting pins to connect the circuit board with the chassis.

21. The apparatus of claim 20, wherein the one or more holes of the chassis comprise a diameter that is large enough to allow an angled insertion of the one or more mounting pins into the one or more holes of the chassis.

22. The apparatus of claim 21, further comprising one or more retainer components, wherein the one or more retainer components hold the one or more mounting pins in the one or more holes of the chassis.

23. The apparatus of claim 20, wherein the chassis with the one or more holes supports a first peripheral portion of the circuit board;
wherein the chassis comprises a ledge to support a second peripheral portion of the circuit board.

24. The apparatus of claim 23, wherein the one or more mounting pins comprise one or more first mounting pins, wherein the second peripheral portion of the circuit board comprises one or more second mounting pins;
wherein the ledge comprises one or more recesses to receive the one or more second mounting pins, wherein the one or more recesses support the second peripheral portion of the circuit board.

25. The apparatus of claim 24, further comprising one or more retainer components, wherein the one or more retainer components hold the one or more second mounting pins in the one or more recesses in the ledge to connect the circuit board with the chassis.

26. The apparatus of claim 20, wherein the one or more holes are designed to only accept the one or more mounting pins of the circuit board if the one or more mounting pins align with the one or more of the one or more holes.

27. The apparatus of claim 26, wherein the one or more holes are designed to only accept the one or more mounting pins if the one or more mounting pins comprise a position, size, and shape that match a position, size, and shape of the one or more holes.

28. An apparatus, comprising:
means for attaching one or more mounting pins to a circuit board; and
means for receiving the one or more mounting pins of the circuit board in a chassis, wherein the means for receiving the one or more mounting pins support the one or more mounting pins to connect the circuit board with the chassis.

29. The apparatus of claim 28, wherein the one or more mounting pins are located on a first peripheral portion of the circuit board, wherein the means for receiving the one or more mounting pins support the first peripheral portion of the circuit board in the chassis, the apparatus further comprising means for supporting a second peripheral portion of the circuit board in the chassis.

30. A method, comprising the step of:
inserting one or more mounting pins of a circuit board into one or more holes in a chassis to connect the circuit board with the chassis.

31. The method of claim 30, wherein the one or more mounting pins comprise one or more first mounting pins located on a first peripheral portion of the circuit board, wherein the chassis with the one or more holes supports the first peripheral portion of the circuit board, the method further comprising the steps of:
positioning a second peripheral portion of the circuit board to rest on a ledge of the chassis for support of the second peripheral portion of the circuit board; and
retaining the second peripheral portion of the circuit board on the ledge of the chassis to hold the circuit board in the chassis.
